(19) United States
(12) Patent Application Publication
(10) Pub. No.: US 2015/0001623 A1
(43) Pub. Date: Jan. 1, 2015

(54) FIELD EFFECT TRANSISTOR AND METHOD FOR FORMING THE SAME

(71) Applicant: TSINGHUA UNIVERSITY, Beijing (CN)

(72) Inventors: Jing Wang, Beijing (CN); Renrong Liang, Beijing (CN); Jun Xu, Beijing (CN)

(73) Assignee: TSINGHUA UNIVERSITY, Beijing (CN)

(21) Appl. No.: 14/110,555

(22) PCT Filed: Aug. 20, 2013
(86) PCT No.: PCT/CN2013/081888

§ 371 Date: Oct. 8, 2013

(30) Foreign Application Priority Data
Jun. 26, 2013 (CN) 201310260078.2

(51) Int. Cl. H01L 29/786; H01L 29/66

(52) U.S. Cl. CPC H01L 29/78654; H01L 29/66742; H01L 29/78681; H01L 29/78684; H01L 29/66772; H01L 29/66969; H01L 29/66068
USPC 257/347; 438/151

(57) ABSTRACT

A field effect transistor and a method for forming the same are provided. The field effect transistor comprises: a substrate (100); an ultra-thin insulator layer (200) formed on the substrate (100), wherein a material of the ultra-thin insulator layer (200) is a monocrystalline rare earth oxide or a monocrystalline beryllium oxide; an ultra-thin semiconductor monocrystalline film (300) formed on the ultra-thin insulator layer (200); and a gate stack (400) formed on the ultra-thin semiconductor monocrystalline film (300), and comprising a gate dielectric (410) and a gate electrode (420) formed on the gate dielectric (410).

### CROSS REFERENCE TO RELATED APPLICATION

This application claims priority and benefits of Chinese Patent Application No. 201310260078.2, filed with State Intellectual Property Office, P. R. C. on Jun. 26, 2013, the entire content of which is incorporated herein by reference.

### FIELD

The present disclosure relates to the semiconductor fabrication field, and more particularly to a field effect transistor and a method for forming the same.

### BACKGROUND

A metal-oxide-semiconductor field effect transistor (MOSFET) has been applied in the integrated circuit (IC) industry for more than 40 years. Various technologies have been invented to decrease its feature size, but basic structure of MOSFET is not changed. However, a design window of an IC, including the performance, dynamic power consumption, static power consumption and device variation, has been decreased to a certain extend where a new transistor structure is needed.

As the gate length shrinks, the transfer characteristics (I_{ds}-V_{gs}) of MOSFET is degraded in two major ways. On one hand, the subthreshold slope increases and the threshold voltage decreases, i.e. the MOS device cannot be turned off easily by lowering the gate voltage (V_{gs}). On the other hand, both the subthreshold slope and the threshold voltage become increasingly sensitive to the variation of the gate length, i.e., device variations become more problematic and the process tolerance of the MOS device becomes rather poor. These phenomena are known as the short channel effects.

Partially depleted silicon on insulator (SOI) MOSFET has no better scaling-down potential than that of the body silicon MOSFET. The partially depleted channel can be changed to be fully depleted by reducing the thickness of a Si film (or the doping concentration of dopants in Si), for example, the thickness of the Si film is reduced from 40 nm to 15 nm. This method may worsen rather than improve the short channel effects, as the fully depleted MOS device eliminates the ground potential provided by the undepleted Si body film. Nevertheless, the researchers have found that if the Si film has a thickness of a few nanometers, the short channel effects would be significantly suppressed. Therefore, an ultra-thin body SOI (UTB-SOI) structure is proposed. As shown in FIG. 1, the Si ultra-thin body is fully depleted so that no evident leakage channels exist, thereby achieving an extremely low off-state current.

On one hand, the UTB-SOI substrate requires the uniformity of the Si film of the SOI wafer is within a range of ±0.5 nm, i.e., less than two Si atomic layers. In other words, an ultra-thin body Si film with a thickness of 5 nm has a non-uniformity of less than ±10%, and it is required that the uniformity exists not only in a single wafer but also from wafer to wafer. In 2009, Soitec, a manufacturer of SOI wafers, developed UTB-SOI wafers that met the above standard, but they were expensive. On the other hand, when the integrated density of the MOSFET device becomes higher and higher, how to dissipate heat will be a serious problem, and therefore it is advantageous that isolation dielectric between devices has high heat conductivity. In particular, for SOI MOSFET devices with a buried silicon dioxide at the bottom of the channel, the silicon dioxide having an amorphous structure has a poor heat conductivity, which is about 1.4 W/m·K. Although a source and drain on insulator (SDOI) structure has been proposed to relieve the heat dissipation problem of the channel, the SDOI structure is difficult to manufacture.

### SUMMARY

The present disclosure is aimed to solve at least one of the problems to some extent or at least to provide a useful commercial choice. Therefore, an objective of the present disclosure is to provide a field effect transistor having a simple structure, low off-state current and excellent heat dissipation performance.

According to embodiments of a first aspect of the present disclosure, a field effect transistor is provided. The field effect transistor comprises: a substrate; an ultra-thin insulator layer formed on the substrate, wherein a material of the ultra-thin insulator layer is a monocrystalline rare earth oxide or a monocrystalline beryllium oxide; an ultra-thin semiconductor monocrystalline film formed on the ultra-thin insulator layer; and a gate stack formed on the ultra-thin semiconductor monocrystalline film, and comprising a gate dielectric and a gate electrode formed on the gate dielectric.

In one embodiment of the present disclosure, the monocrystalline rare earth oxide comprises at least one oxide selected from a group consisting of: (Gd₁₋ₓErₓ)₂O₃, (Gd₁₋ₓNdₓ)₂O₃, (Er₁₋ₓNdₓ)₂O₃, (Er₁₋ₓLaₓ)₂O₃, (Pr₁₋ₓLaₓ)₂O₃, (Pr₁₋ₓNdₓ)₂O₃, and (Pr₁₋ₓGdₓ)₂O₃, where x is within a range of 0 to 1.

In one embodiment of the present disclosure, the ultra-thin insulator layer has a thickness of less than 20 nm.

In one embodiment of the present disclosure, the ultra-thin semiconductor monocrystalline film has a thickness of less than 20 nm.

In one embodiment of the present disclosure, the field effect transistor further comprises: a back gate formed in the substrate and immediately adjacent to the ultra-thin insulator layer.

In one embodiment of the present disclosure, the ultra-thin insulator layer and the ultra-thin semiconductor monocrystalline film are formed by epitaxial growth.

In one embodiment of the present disclosure, a material of the substrate comprises at least one semiconductor selected from a group consisting of: monocrystalline Si, monocrystalline SiGe, and monocrystalline Ge.

In one embodiment of the present disclosure, a material of the ultra-thin semiconductor monocrystalline film comprises: Si, Ge, Si_{1-y}Ge_{y}, Si_{1-z}C_{z}, a group III-V compound semiconductor material and a group II-VI compound semiconductor material, where y and z are each within a range of 0 to 1.

In one embodiment of the present disclosure, the ultra-thin insulator layer is strained.

In one embodiment of the present disclosure, the ultra-thin semiconductor monocrystalline film is strained.

As stated above, the field effect transistor according to embodiments of the present disclosure has the following advantages.

1) Compared with a conventional MOSFET device formed by a UTB-SOI wafer with buried SiO₂ as an insulator, the field effect transistor provided in embodiments of the present disclosure is easier to manufacture. As the ultra-thin rare earth oxide or beryllium oxide monocrystalline layer and the ultra-thin semiconductor monocrystalline film could be formed by epitaxial growth, the thicknesses of the ultra-thin rare earth oxide or beryllium oxide monocrystalline layer and the ultra-thin semiconductor monocrystalline film can be precisely controlled during the epitaxial growth process. Thus, a good value (such as ±0.5 nm or better) of the thickness deviation within a single wafer or from wafer to wafer can be easily achieved.

2) The field effect transistor according to embodiments of the present disclosure can be obtained by a method compatible with a conventional MOSFET process, in which the fabrication process is simple and has low manufacture cost and can be applied in large-scale production.

3) The heat conductivity of the rare earth oxide or beryllium oxide monocrystalline layer is higher than that of the buried oxide (BOX) in the conventional UTB-SOI wafer, in which SiO₂ has a poor heat conductivity of 1.4 W/m·K. The heat conductivity of the rare earth oxide is more than three times that of SiO₂. The heat conductivity of beryllium oxide can reach 250-300 W/m·K, while the heat conductivity of gold is 318 W/m·K, and the heat conductivity of aluminum is 250 W/m·K, which means that the heat conductivity of the beryllium oxide monocrystal is substantially equal to that of the metal aluminum. Thus, the heat dissipation capability of a device can be dramatically improved if the rare earth oxide or beryllium oxide monocrystalline layer is used as the ultra-thin insulator layer.

4) The ultra-thin rare earth oxide monocrystalline layer and the ultra-thin beryllium oxide monocrystalline layer are both insulator, which may not only play a role of heat dissipation but also could act as substrate isolation after the field effect transistor (such as MOSFET) is completed. Meanwhile, the relative dielectric constants (k value) of the rare earth oxide and beryllium oxide are both higher than that of SiO₂. For example, the k value of beryllium oxide is 6.8, and the k value of the rare earth oxide is higher than that of beryllium oxide, which can reach above 15-20. Therefore, the ultra-thin insulator layer can also act as a gate dielectric of the back gate, which forms a double-gate device structure having a top gate and a back gate, thus greatly improving the short channel effects of the device.

Another objective of the present disclosure is to provide a method for forming the field effect transistor which has good performance, in which the method is compatible with other techniques.

According to embodiments of a second aspect of the present disclosure, a method for forming the field effect transistor is provided. The method comprises steps of: providing a substrate; forming an ultra-thin insulator layer on the substrate, wherein a material of the ultra-thin insulator layer is a monocrystalline rare earth oxide or a monocrystalline beryllium oxide; forming an ultra-thin semiconductor monocrystalline film on the ultra-thin insulator layer; and forming a gate stack on the ultra-thin semiconductor monocrystalline film, wherein the gate stack comprises a gate dielectric and a gate electrode formed on the gate dielectric.

In one embodiment of the disclosure, the monocrystalline rare earth oxide comprises at least one oxide selected from a group consisting of: (Gd₁₋ₓErₓ)₂O₃, (Gd₁₋ₓNdₓ)₂O₃, (Er₁₋ₓNdₓ)₂O₃, (Er₁₋ₓLaₓ)₂O₃, (Pr₁₋ₓLaₓ)₂O₃, (Pr₁₋ₓNdₓ)₂O₃, and (Pr₁₋ₓGdₓ)₂O₃, where x is within a range of 0 to 1.

In one embodiment of the disclosure, the ultra-thin insulator layer has a thickness of less than 20 nm.

In one embodiment of the disclosure, the ultra-thin semiconductor monocrystalline film has a thickness of less than 20 nm.

In one embodiment of the disclosure, the method further comprises forming a back gate in the substrate and immediately adjacent to the ultra-thin insulator film before forming the gate stack.

In one embodiment of the disclosure, the ultra-thin insulator layer and the ultra-thin semiconductor monocrystalline film are formed by epitaxial growth.

In one embodiment of the disclosure, a material of the substrate comprises at least one semiconductor selected from a group consisting of: monocrystalline Si, monocrystalline SiGe, and monocrystalline Ge.

In one embodiment of the disclosure, a material of the ultra-thin semiconductor monocrystalline film comprises: Si, Ge, Si_{1-y}Ge_{y}, Si_{1-z}C_{z}, a group III-V compound semiconductor material and a group II-VI compound semiconductor material, where y and z are each within a range of 0 to 1.

In one embodiment of the disclosure, the ultra-thin insulator layer is strained.

In one embodiment of the disclosure, the ultra-thin semiconductor monocrystalline film is strained.

As stated above, the method for forming the field effect transistor according to embodiments of the present disclosure has the following advantages.

1) Compared with a conventional MOSFET device formed by a UTB-SOI wafer with buried SiO₂ as an insulator, the solid state electronic device structure (such as the field effect transistor) provided in embodiments of the present disclosure is easier to manufacture. As the ultra-thin rare earth oxide or beryllium oxide monocrystalline layer and the ultra-thin semiconductor monocrystalline film could be formed by epitaxial growth, the thicknesses of the ultra-thin rare earth oxide or beryllium oxide monocrystalline layer and the ultra-thin semiconductor monocrystalline film can be precisely controlled during the epitaxial growth process. Thus, a good value (such as ±0.5 nm or better) of the thickness deviation within a single wafer or between wafers can be easily achieved.

2) The field effect transistor according to embodiments of the present disclosure can be obtained by a combination of a conventional MOSFET process and the method disclosed in the present disclosure, in which the fabrication process is simple and has low manufacture cost and can be applied in large-scale production.

3) The heat conductivity of the rare earth oxide or beryllium oxide monocrystalline layer is higher than that of the buried oxide (BOX) in the conventional UTB-SOI wafer, in which SiO₂ has a poor heat conductivity of 1.4 W/m·K. The heat conductivity of the rare earth oxide is more than three times that of SiO₂. The heat conductivity of beryllium oxide can reach 250-300 W/m·K, while the heat conductivity of gold is 318 W/m·K, and the heat conductivity of aluminum is 250 W/m·K, which means that the heat conductivity of the beryllium oxide monocrystal is substantially equal to that of the metal aluminum. Thus, the heat dissipation capability of a device can be dramatically improved if the rare earth oxide or beryllium oxide monocrystalline layer is used as the ultra-thin insulator layer.

4) The ultra-thin rare earth oxide monocrystalline layer and the ultra-thin beryllium oxide monocrystalline layer are both insulator, which may not only play a role of heat dissipation but also could act as substrate isolation after the field effect transistor (such as MOSFET) is completed. Meanwhile, the relative dielectric constants (k value) of the rare earth oxide and beryllium oxide are both higher than that of SiO₂. For example, the k value of beryllium oxide is 6.8, and the k value of the rare earth oxide is higher than that of beryllium oxide, which can reach above 15-20. Therefore, the ultra-thin insulator layer can also act as a gate dielectric of the back gate, which forms a double-gate device structure having a top gate and a back gate, thus greatly improving the short channel effects of the device.

Additional aspects and advantages of the embodiments of the present disclosure will be given in part in the following descriptions, become apparent in part from the following descriptions, or be learned from the practice of the embodiments of the present disclosure.

### BRIEF DESCRIPTION OF THE DRAWINGS

These and other aspects and advantages of the disclosure will become apparent and more readily appreciated from the following descriptions taken in conjunction with the drawings in which:

FIG. 1 is a schematic cross-sectional view of a conventional ultra-thin body silicon on insulator (UTB-SOI) MOSFET;

FIG. 2 is a schematic cross-sectional view of a field effect transistor according to an embodiment of the present disclosure;

FIG. 3 is a schematic cross-sectional view of an N-type MOSFET device with a back gate and raised source and drain structures according to an embodiment of the present disclosure;

FIG. 4 is a schematic cross-sectional view of a P-type MOSFET device with a back gate and raised source and drain structures according to an embodiment of the present disclosure;

FIGS. 5(a)-5(b) are schematic views showing the leading out of a back gate contact of a field effect transistor according to an embodiment of the present disclosure; and

FIG. 6 is a flow chart of a method for forming a field effect transistor according to an embodiment of the present disclosure.

### DETAILED DESCRIPTION

Embodiments of the present disclosure will be described in detail in the following descriptions, examples of which are shown in the accompanying drawings, in which the same or similar elements and elements having same or similar functions are denoted by like reference numerals throughout the descriptions. The embodiments described herein with reference to the accompanying drawings are explanatory and illustrative, which are used to generally understand the present disclosure. The embodiments shall not be construed to limit the present disclosure.

It is to be understood that phraseology and terminology used herein with reference to device or element orientation (such as, terms like “longitudinal”, “lateral”, “front”, “rear”, “right”, “left”, “lower”, “upper”, “horizontal”, “vertical”, “above”, “below”, “up”, “top”, “bottom” as well as derivative thereof such as “horizontally”, “downwardly”, “upwardly”, etc.) are only used to simplify description of the present disclosure, and do not alone indicate or imply that the device or element referred to must have or operated in a particular orientation.

In addition, terms such as “first” and “second” are used herein for purposes of description and are not intended to indicate or imply relative importance or significance. Thus, the feature defined with “first” and “second” may comprise one or more this feature. In the description of the present disclosure, “a plurality of” means two or more than two, unless specified otherwise.

Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

In the description of the present disclosure, a structure in which a first feature is “on” a second feature may include an embodiment in which the first feature directly contacts the second feature, and may also include an embodiment in which an additional feature is formed between the first feature and the second feature so that the first feature does not directly contact the second feature, unless specified otherwise. Furthermore, a first feature “on,” “above,” or “on top of” a second feature may include an embodiment in which the first feature is right “on,” “above,” or “on top of” the second feature, and may also include an embodiment in which the first feature is not right “on,” “above,” or “on top of” the second feature, or just means that the first feature is at a height higher than that of the second feature. While a first feature “beneath,” “below,” or “on bottom of” a second feature may include an embodiment in which the first feature is right “beneath,” “below,” or “on bottom of” the second feature, and may also include an embodiment in which the first feature is not right “beneath,” “below,” or “on bottom of” the second feature, or just means that the first feature is at a height lower than that of the second feature.

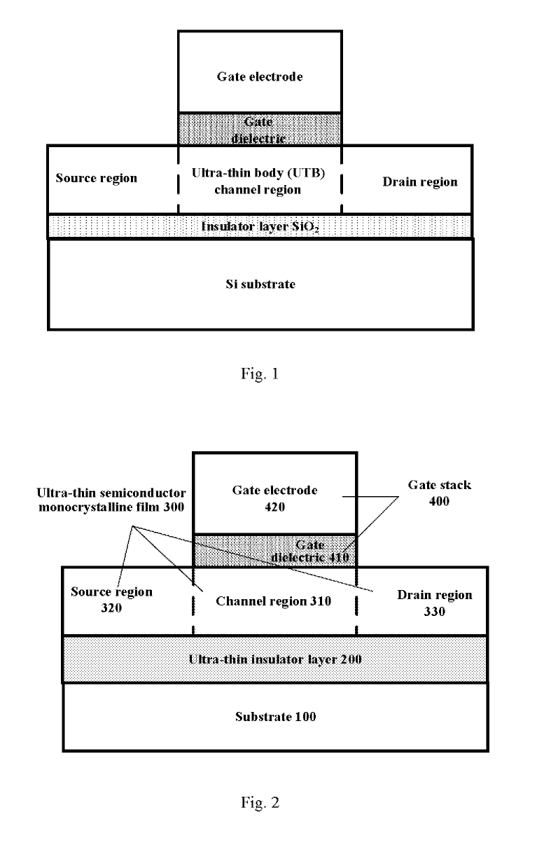

According to embodiments of a first aspect of the present disclosure, a field effect transistor is provided. As shown in FIG. 2, the field effect transistor comprises: a substrate 100; an ultra-thin insulator layer 200 formed on the substrate 100; an ultra-thin semiconductor monocrystalline film 300 formed on the ultra-thin insulator layer 200; and a gate stack 400 formed on the ultra-thin semiconductor monocrystalline film 300. The gate stack 400 comprises a gate dielectric 410 and a gate electrode 420 formed on the gate dielectric 410. The ultra-thin semiconductor monocrystalline film 300 comprises a channel region 310 under the gate stack 400, and a source region 320 and a drain region 330 on both sides of the gate stack 400. With reference to FIG. 2, the source region 320 is formed on the left side of the channel region 310, and the drain region 330 is formed on the right side of the channel region 310.

In one embodiment of the present disclosure, a material of the ultra-thin insulator layer 200 is a monocrystalline rare earth oxide or a monocrystalline beryllium oxide. Specifically, the monocrystalline rare earth oxide comprises at least one oxide selected from the group consisting of: (Gd₁₋ₓErₓ)₂O₃, (Gd₁₋ₓNdₓ)₂O₃, (Er₁₋ₓNdₓ)₂O₃, (Er₁₋ₓLaₓ)₂O₃, (Pr₁₋ₓLaₓ)₂O₃, (Pr₁₋ₓNdₓ)₂O₃, and (Pr₁₋ₓGdₓ)₂O₃, where x is within a range of 0 to 1.

The field effect transistor according to embodiments of the present disclosure differs from a conventional UTB-SOI MOSFET in that the monocrystalline rare earth oxide or the monocrystalline beryllium oxide is used instead of amorphous SiO₂. Among rare earth elements, most actinide elements are radioactive, and therefore it is preferable to use lanthanide rare earth oxides. Both the crystal structures of the rare earth oxide and a common semiconductor material such as Si, Ge, SiGe, and GaAs belong to a cubic crystal system. Furthermore, the difference between lattice constants of lanthanide rare earth oxide crystals such as La₂O₃, Pr₂O₃, Nd₂O₃, Er₂O₃, and Gd₂O₃ is quite small, and the lattice constant of a lanthanide rare earth oxide crystal is approximately twice of that of a Si crystal or a Ge crystal. In other words, one unit cell of the rare earth oxide crystal is matched with two unit cells of the Si crystal or the Ge crystal, i.e., the lattice constant of the rare earth oxide crystal is substantially matched with that of the Si crystal or the Ge crystal, which not only facilitates the formation of a semiconductor film on the rare earth oxide layer by epitaxy but also the formation of a rare earth oxide monocrystalline film on the semiconductor film by epitaxy.

Similarly, both the crystal structures of the beryllium oxide and the common semiconductor material such as Si, Ge, SiGe, and GaAs belong to a cubic crystal system. Furthermore, the lattice constant of the beryllium oxide crystal is approximately half that of the Si crystal, that is, one unit cell of the Si crystal is matched with two unit cells of the beryllium oxide crystal, i.e., the lattice constant of the Si crystal is substantially matched with that of the beryllium oxide crystal, which not only facilitates the formation of a semiconductor monocrystalline film on the beryllium oxide monocrystalline film by epitaxy but also the formation of a beryllium oxide monocrystalline film on the semiconductor monocrystalline film by epitaxy. Therefore, by employing the lattice match between the rare earth oxide crystal or the beryllium oxide crystal and the common semiconductor material crystal, the fabrication process of the field effect transistor according to embodiments of the present disclosure is simplified and the yield of an IC chip is significantly improved. Other beneficial effects brought by the use of a monocrystalline rare earth oxide layer or a monocrystalline beryllium oxide layer as an insulator buried layer will be further described below.

In one embodiment of the present disclosure, the gate dielectric 410 has a high dielectric constant, i.e., the gate dielectric 410 is a high k dielectric, which includes, but is not limited to, a metallic oxide dielectric, such as titanium oxide, tantalum oxide, hafnium oxide, and zirconium oxide. The material of the gate electrode 420 includes, but is not limited to, at least one compound selected from the group consisting of: polycrystalline Si, Ti, Zr, Hf, Ta and Al, or comprises an alloy material having metallic characteristics, such as TaN and TiN.

In one embodiment of the present disclosure, the ultra-thin insulator layer 200 has a thickness of less than 20 nm, preferably less than 10 nm, and more preferably less than 5 nm. As described above, the material of the ultra-thin insulator layer 200 is the rare earth oxide monocrystal or the beryllium oxide monocrystal, the lattice constant of which may be not perfectly matched with that of a common substrate, for example, a Si substrate, a SiGe substrate, or a Ge substrate. Therefore, when a rare earth oxide monocrystal or a beryllium oxide monocrystal is formed on the common substrate by epitaxy, the epitaxial layer may have a critical thickness due to an imperfect match between the lattice constants of the ultra-thin insulator layer 200 and the substrate 100. When the thickness of the epitaxial layer exceeds the critical thickness, various defects may be generated, such as dislocations, stacking faults, or twins. These defects may degrade the performances of the field effect transistor. Therefore, the ultra-thin rare earth oxide monocrystal or the ultra-thin beryllium oxide monocrystal is applied in embodiments of the present disclosure. On one hand, unnecessary defects may be avoided, and the quality of the formed field effect transistor is improved. On the other hand, this technique facilitates the heat dissipation of the field effect transistor, because the heat conductivity of the rare earth oxide monocrystal or the beryllium oxide monocrystal is far higher than that of a conventional amorphous SiO₂. For example, the heat conductivity of the rare earth oxide is more than three times that of SiO₂, and the heat conductivity of the beryllium oxide is higher than that of the rare earth oxide, which is substantially the same as that of aluminum.

In one embodiment of the present disclosure, the ultra-thin semiconductor monocrystalline film 300 has a thickness of less than 20 nm, i.e., the channel region 310 has a thickness of less than 20 nm. Preferably, the ultra-thin semiconductor monocrystalline film 300 has a thickness of less than 10 nm, more preferably less than 5 nm. When the ultra-thin semiconductor monocrystalline film 300 is very thin, especially when the thickness of the ultra-thin semiconductor monocrystalline film 300 is less than the gate length, the short channel effects will be suppressed very well, and the subthreshold slope may be close to the theoretical limit, around 62 mV/decade at room temperature. For example, if a gate with a length of 11 nm can be fabricated by photolithography and etching, only a channel region with a thickness of not more than 11 nm needs to be fabricated. Likewise, if a gate with a length of 5 nm can be fabricated by photolithography and etching, only a channel region with a thickness of not more than 5 nm needs to be fabricated.

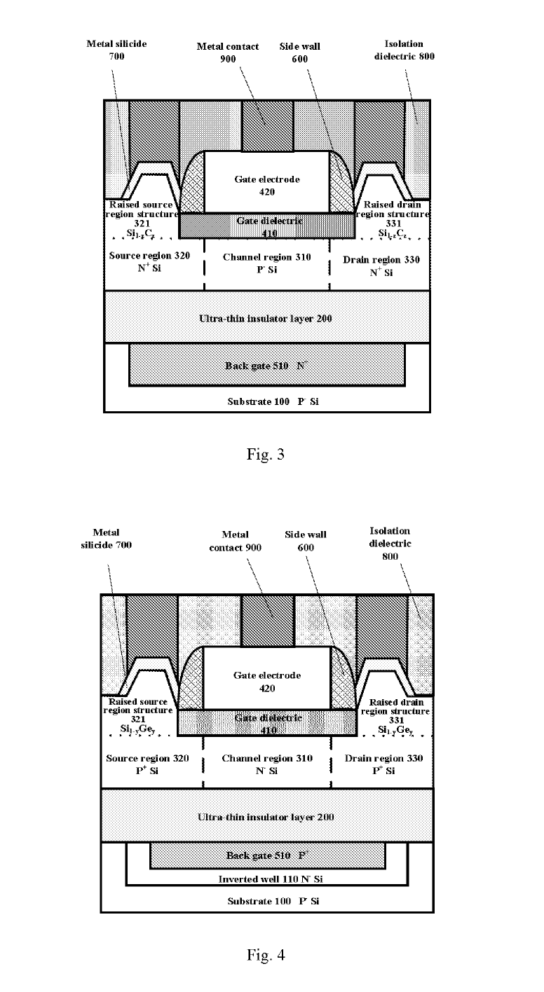

In one embodiment of the present disclosure, as shown in FIG. 3 and FIG. 4, the field effect transistor further comprises a back gate 510. Back gates 510 in NMOSFET and PMOSFET are shown in FIG. 3 and FIG. 4, respectively. As shown in FIGS. 3-4, the back gate 510 is formed in the substrate 100 and immediately adjacent to the ultra-thin insulator layer 200. In this case, the back gate 510 and the ultra-thin insulator layer 200 form a “gate stack”, which provides the device with a double gate structure having a top gate and a back gate. The material of the ultra-thin insulator layer 200 comprises a rare earth oxide or beryllium oxide, which has a high dielectric constant (k value). In one embodiment, the k value of beryllium oxide is 6.8, and the k value of the rare earth oxide is higher than that of beryllium oxide. By reducing the thickness of the ultra-thin insulator layer 200, the back gate 510 has better control over the channel region. In one preferred embodiment of the present disclosure, the ultra-thin insulator layer 200 has a thickness of less than 10 nm, and more preferably less than 5 nm.

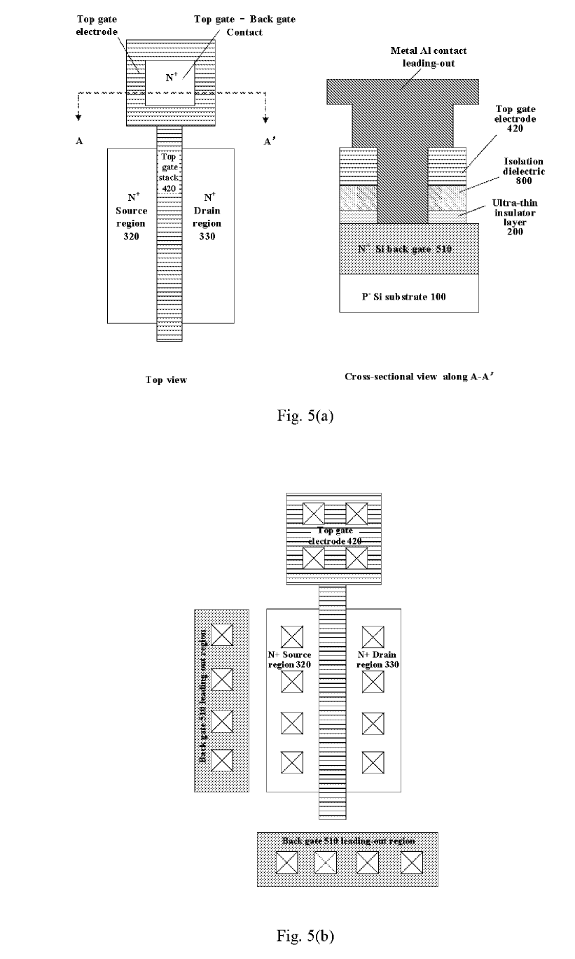

It should be noted that, as shown in FIG. 3, for an N-type MOSFET device, the substrate 100 is P-type lightly doped, while the back gate 510 is N-type heavily doped. As shown in FIG. 4, for a P-type MOSFET, if a back gate leading-out region needs to be formed on a P-type lightly doped Si wafer substrate, an N-type lightly doped inverted well 110 is formed firstly, and then a P-type heavily doped back gate leading-out region is formed, which aims to form an effective isolation between the devices. FIG. 5(a) and FIG. 5(b) schematically present two leading-out methods of the back gate electrodes, respectively. Taking the N-type MOSFET device as an example, in FIG. 5(a), the left figure is a schematic view of a transistor layout and the right figure is a cross-sectional view of the transistor along a line A-A′ in the left figure. With the arrangement as shown in the FIG. 5(a), the top gate electrode can be connected to the back gate electrode. In FIG. 5(b), the back gate electrodes can be disposed on a side of the source region or the drain region, or a side of the top gate electrode, and thus the back gate electrode is led out independently. The arrangement as shown in the FIG. 5(b) facilitates the adjustment of the threshold voltage of MOSFET devices, which is valuable for the power supply management of ICs, particularly for that of analog circuits.

In one embodiment of the present disclosure, the ultra-thin insulator layer 200 and the ultra-thin semiconductor monocrystalline film 300 are formed by epitaxial growth. Specifically, the epitaxial growth technique comprises solid source epitaxy, atomic layer deposition, molecular beam epitaxy, ultra-high vacuum chemical vapor deposition, reduced pressure chemical vapor deposition, and so on. The films formed by epitaxial growth have good lattice quality and less defects. In addition, the thickness of the epitaxial layers can be precisely controlled during the epitaxy. Thus, the films developed in the present disclosure can be applied in large-scale production.

In one embodiment of the present disclosure, the source region 320 and the drain region 330 have a doping type opposite to or the same as that of the channel region 310. When the doping type of the source region 320 and the drain region 330 is opposite to that of the channel region 310, i.e., a MOSFET device with a conventional N⁺—P⁻—N⁺ or P⁺—N⁻—P⁺ structure is formed, the device operates in an inversion mode. When the doping type of the source region 320 and the drain region 330 is the same as that of channel region 310, a junctionless field effect transistor with a N⁺—N⁺—N⁻ or P⁺—P⁺—P⁺ structure is formed, and the device operates in an accumulation mode. As the scaling down of the feature size of the transistor, it is more and more difficult to prepare a PN junction with super-steep doping profile. Therefore, the junctionless field effect transistor could be potentially implemented in a technology node of 11 nm and beyond.

In one embodiment of the present disclosure, a material of the substrate 100 comprises at least one semiconductor selected from the group consisting of: monocrystalline Si, monocrystalline SiGe and monocrystalline Ge. These materials have low cost and can be easily applied in large-scale production. Moreover, the lattice constants of these materials are matched with the lattice constant of the ultra-thin insulator layer 200.

In one embodiment of the present disclosure, a material of the ultra-thin semiconductor monocrystalline film 300 comprises at least one semiconductor selected from the group consisting of: Si, Ge, Si_{1-y}Ge_{y} (0<y<1), Si_{1-z}C_{z} (0<z<1), a group III-V compound semiconductor material and a group II-VI compound semiconductor material.

In one embodiment of the present disclosure, the source region 320 and the drain region 330 each have raised source and drain structures. As shown in FIG. 3, for the N-type MOSFET device, a Si_{1-z}C_{z} (0<z<1) raised source region structure 321 and a Si_{1-z}C_{z} (0<z<1) raised drain region structure 331 are simultaneously formed in the source region 320 and the drain region 330, respectively. This method not only can significantly decrease the series resistance in the source/drain region but also introduce a uniaxial tensile strain in the Si channel. As shown in FIG. 4, for the P-type MOSFET device, the channel region 310 is N-type weakly doped, the source region 320 and the drain region 330 are P-type heavily doped, and a raised source/drain structure can be formed by using selective Si_{1-y}Ge_{y} (0<y<1) epitaxy, thus introducing a uniaxial compressive strain in the Si channel. In order to form a functional field effect transistor, in one preferred embodiment of the present disclosure, the field effect transistor is further subjected to the following steps: lightly doped drain (LDD) implantation, dopant activation, forming a side wall 600, forming a metal silicide layer 700, forming an isolation dielectric 800, and forming a metal contact 900, as shown in FIG. 3 and FIG. 4.

In one embodiment of the present disclosure, the ultra-thin insulator layer 200 is strained. As described above, the material of the ultra-thin insulator layer 200 is a monocrystalline rare earth oxide or a monocrystalline beryllium oxide, whose lattice constants may be substantially but not perfectly matched with that of the monocrystalline Si. For example, the lattice constant of beryllium oxide is 0.27 nm, which is slightly lower than a half of the lattice constant (0.543 nm) of Si, while the lattice constants of rare earth oxides such as (Gd₁₋ₓNdₓ)₂O₃ may be slightly higher or lower than twice of the lattice constant of Si due to a slight difference in the rare earth components. Thus, when a conventional Si wafer is used as a substrate, a strain can be formed in the ultra-thin insulator layer as a perfect match of lattices may not be easily obtained. Since the lattice mismatch of this kind is small, i.e., the strain level is small, and the insulator layer is ultra-thin, the ultra-thin insulator layer may not be strain-relaxed. Thus, a damage to the crystal structure of the ultra-thin insulator could be avoided because no dislocation will be generated.

In one embodiment of the present disclosure, the ultra-thin semiconductor monocrystalline film 300 is strained. When the material of the substrate is Si and the material of the ultra-thin semiconductor monocrystalline film is not Si, for example, the material of the ultra-thin semiconductor monocrystalline film is monocrystalline SiGe, a biaxial compressive strain would be introduced in the ultra-thin monocrystalline SiGe film within the critical thickness due to the lattice mismatch between SiGe and Si. Moreover, the introduction of the compressive strain facilitates an increase in the hole mobility, thus enhancing the performance of the P-type MOSFET. When the material of the ultra-thin semiconductor monocrystalline film is monocrystalline Si_{1-z}C_{z} (0<z<1), a biaxial tensile strain is introduced in the ultra-thin semiconductor Si monocrystalline film, thus enhancing the performance of the N-type MOSFET.

As described above, the field effect transistor according to embodiments of the present disclosure has the following advantages.

1) Compared with a conventional MOSFET device formed by a UTB-SOI wafer with buried SiO₂ as an insulator, the field effect transistor provided in embodiments of the present disclosure is easier to manufacture. As the ultra-thin rare earth oxide or beryllium oxide monocrystalline layer and the ultra-thin semiconductor monocrystalline film could be formed by epitaxial growth, the thicknesses of the ultra-thin rare earth oxide or beryllium oxide monocrystalline layer and the ultra-thin semiconductor monocrystalline film can be precisely controlled during the epitaxial growth process. Thus, a good value (such as ±0.5 nm or better) of the thickness deviation within a single wafer or between wafers can be easily achieved.

2) The field effect transistor according to embodiments of the present disclosure can be obtained by a method compatible with a conventional MOSFET process, in which the fabrication process is simple and has low manufacture cost and can be applied in large-scale production.

3) The heat conductivity of the rare earth oxide or beryllium oxide monocrystalline layer is higher than that of the buried oxide (BOX) in the conventional UTB-SOI wafer, in which SiO₂ has a poor heat conductivity of 1.4 W/m·K. The heat conductivity of the rare earth oxide is more than three times that of SiO₂. The heat conductivity of beryllium oxide can reach 250-300 W/m·K, while the heat conductivity of gold is 318 W/m·K, and the heat conductivity of aluminum is 250 W/m·K, which means that the heat conductivity of the beryllium oxide monocrystal is substantially equal to that of the metal aluminum. Thus, the heat dissipation capability of a device can be dramatically improved if the rare earth oxide or beryllium oxide monocrystalline layer is used as the ultra-thin insulator layer.

4) The ultra-thin rare earth oxide monocrystalline layer and the ultra-thin beryllium oxide monocrystalline layer are both insulator, which may not only play a role of heat dissipation but also could act as substrate isolation after the field effect transistor (such as MOSFET) is completed. Meanwhile, the relative dielectric constants (k value) of the rare earth oxide and beryllium oxide are both higher than that of SiO₂. For example, the k value of beryllium oxide is 6.8, and the k value of the rare earth oxide is higher than that of beryllium oxide, which can reach above 15-20. Therefore, the ultra-thin insulator layer can also act as a gate dielectric of the back gate, which forms a double-gate device structure having a top gate and a back gate, thus greatly improving the short channel effects of the device.

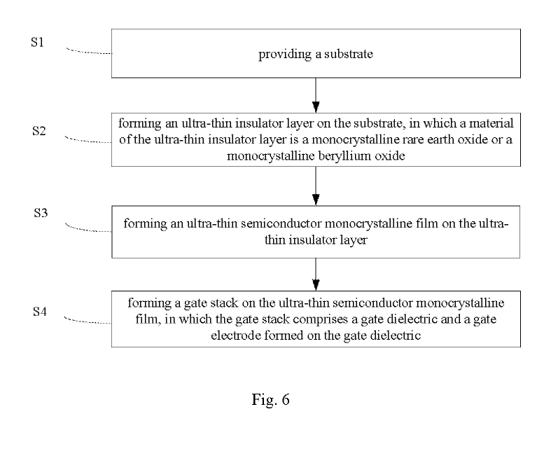

According to embodiments of a second aspect of the present disclosure, a method for forming the field effect transistor is provided. As shown in FIG. 6, the method comprises:

S1) providing a substrate 100;

S2) forming an ultra-thin insulator layer 200 on the substrate 100, in which a material of the ultra-thin insulator layer 200 is a monocrystalline rare earth oxide or a monocrystalline beryllium oxide;

S3) forming an ultra-thin semiconductor monocrystalline film 300 on the ultra-thin insulator layer 200; and

S4) forming a gate stack 400 on the ultra-thin semiconductor monocrystalline film 300, in which the gate stack 400 comprises a gate dielectric 410 and a gate electrode 420 formed on the gate dielectric 410.

In one preferred embodiment of the present disclosure, the monocrystalline rare earth oxide comprises at least one oxide selected from the group consisting of: (Gd₁₋ₓErₓ)₂O₃, (Gd₁₋ₓNdₓ)₂O₃, (Er₁₋ₓNdₓ)₂O₃, (Er₁₋ₓLaₓ)₂O₃, (Pr₁₋ₓLaₓ)₂O₃, (Pr₁₋ₓNdₓ)₂O₃, and (Pr₁₋ₓGdₓ)₂O₃, where x is within a range of 0 to 1.

In one preferred embodiment of the present disclosure, the ultra-thin insulator layer 200 has a thickness of less than 20 nm, preferably less than 10 nm, and more preferably less than 5 nm.

In one preferred embodiment of the present disclosure, the ultra-thin semiconductor monocrystalline film 300 has a thickness of less than 20 nm, preferably less than 10 nm, and more preferably less than 5 nm.

In one embodiment of the present disclosure, the method further comprises forming a back gate 510 in the substrate 100 and immediately adjacent to the ultra-thin insulator film 200 before forming the gate stack 400. Usually, in order to form a heavily doped back gate, ion implantation and dopant activation are needed. These steps can be performed before or after the ultra-thin insulator layer 200 is formed, which depends on the specific process flow. In one embodiment, the back gate 510 is formed by ion implantation and dopant activation after both the ultra-thin insulator layer 200 and the ultra-thin semiconductor monocrystalline film 300 are formed.

In one embodiment of the present disclosure, the ultra-thin insulator layer 200 and the ultra-thin semiconductor monocrystalline film 300 are formed by epitaxial growth.

In one embodiment of the present disclosure, the source region 320 and the drain region 330 each have a doping type opposite to or the same as that of the channel region 310.

In one embodiment of the present disclosure, a material of the substrate 100 comprises at least one semiconductor selected from the group consisting of: monocrystalline Si, monocrystalline SiGe, and monocrystalline Ge.

In one embodiment of the present disclosure, a material of the ultra-thin semiconductor monocrystalline film 300 comprises: Si, Ge, Si_{1-y}Ge_{y}, Si_{1-z}C_{z}, a group III-V compound semiconductor material and a group II-VI compound semiconductor material, where y and z are each within a range of 0 to 1.

In one embodiment of the present disclosure, the source region 320 has a raised source region structure 321, and the drain region 330 has a raised drain region structure 331.

In one embodiment of the present disclosure, the ultra-thin insulator layer 200 is strained.

In one embodiment of the present disclosure, the ultra-thin semiconductor monocrystalline film 300 is strained.

As stated above, the method for forming the field effect transistor according to embodiments of the present disclosure has the following advantages.

1) Compared with a conventional MOSFET device formed by a UTB-SOI wafer with buried SiO₂ as an insulator, the solid state electronic device structure (such as the field effect transistor) provided in embodiments of the present disclosure is easier to manufacture. As the ultra-thin rare earth oxide or beryllium oxide monocrystalline layer and the ultra-thin semiconductor monocrystalline film could be formed by epitaxial growth, the thicknesses of the ultra-thin rare earth oxide or beryllium oxide monocrystalline layer and the ultra-thin semiconductor monocrystalline film can be precisely controlled during the epitaxial growth process. Thus, a good value (such as ±0.5 nm or better) of the thickness deviation within a single wafer or between wafers can be easily achieved.

2) The field effect transistor according to embodiments of the present disclosure can be obtained by a combination of a conventional MOSFET method and the method disclosed in the present disclosure, in which the fabrication process is simple and has low manufacture cost and can be applied in large-scale production.

3) The heat conductivity of the rare earth oxide or beryllium oxide monocrystalline layer is higher than that of the buried oxide (BOX) in the conventional UTB-SOI wafer, in which SiO₂ has a poor heat conductivity of 1.4 W/m·K. The heat conductivity of the rare earth oxide is more than three times that of SiO₂. The heat conductivity of beryllium oxide can reach 250-300 W/m·K, while the heat conductivity of gold is 318 W/m·K, and the heat conductivity of aluminum is 250 W/m·K, which means that the heat conductivity of the beryllium oxide monocrystal is substantially equal to that of the metal aluminum. Thus, the heat dissipation capability of a device can be dramatically improved if the rare earth oxide or beryllium oxide monocrystalline layer is used as the ultra-thin insulator layer.

4) The ultra-thin rare earth oxide monocrystalline layer and the ultra-thin beryllium oxide monocrystalline layer are both insulator, which may not only play a role of heat dissipation but also could act as substrate isolation after the field effect transistor (such as MOSFET) is completed. Meanwhile, the relative dielectric constants (k value) of the rare earth oxide and beryllium oxide are both higher than that of SiO₂. For example, the k value of beryllium oxide is 6.8, and the k value of the rare earth oxide is higher than that of beryllium oxide, which can reach above 15-20. Therefore, the ultra-thin insulator layer can also act as a gate dielectric of the back gate, which forms a double-gate device structure having a top gate and a back gate, thus greatly improving the short channel effects of the device.

The method for forming the field effect transistor according to embodiments of the present disclosure is described in detail below with reference to the following embodiments, so that those skilled in the art may better understand the method of the present disclosure.

First, a Si substrate is provided.

Secondly, an ultra-thin insulator layer is grown on the Si substrate, in which a material of the ultra-thin insulator layer is a monocrystalline rare earth oxide or a monocrystalline beryllium oxide.

In an embodiment, by using a MOCVD system with an Nd(thd)₃ (tri(2,2,6,6-tetramethyl-3,5-heptanedionato) neodymium) as a metal precursor and O₃ as an oxygen source, an ultra-thin Nd₂O₃ film with a thickness of 5 nm is deposited at a temperature of 850° C. In another embodiment, an ultra-thin monocrystalline BeO film is grown at a temperature of 600° C. to 1200° C. by means of solid source epitaxy. During the epitaxy, Be(CH₃)₂ and O₂ are used as Be and O sources, respectively, and the base pressure of the chamber is in the range of 10⁻⁵ Torr to 10⁻¹² Torr. In a further embodiment, an ultra-thin monocrystalline BeO film is grown in an atom layer deposition system. Be(CH₃)₂ (dimethyl beryllium) and H₂O are used as Be and O sources, respectively. The deposition temperature can be varied from room temperature to 450° C., preferably 250° C. As the lattice constant of the rare earth oxide Nd₂O₃ is more than twice that of the Si, a compressive strain is introduced in the ultra-thin Nd₂O₃ film.

Then, an ultra-thin monocrystalline semiconductor material is grown on the monocrystalline rare earth oxide film or monocrystalline beryllium oxide film. For example, an ultra-thin monocrystalline Si film with a thickness of 5 nm is formed on an ultra-thin Nd₂O₃ film with a thickness of 5 nm by epitaxy, or an ultra-thin monocrystalline Si_{1-y}Ge_{y} film with a thickness of 5 nm is formed on an ultra-thin Nd₂O₃ film with a thickness of 5 nm by epitaxy. As the lattice constant of Si_{1-y}Ge_{y} is larger than that of Si, a compressive strain is introduced in the ultra-thin Si_{1-y}Ge_{y} film. Therefore, the thermal budget of the subsequent MOSFET fabrication steps must be strictly controlled. A strained Si_{1-y}Ge_{y} film has a higher hole mobility compared with a strained Si film, which improves the performance of PMOSFET.

Finally, process steps in conventional CMOS technology such as the back gate ion implantation, the source and drain doping, forming a gate dielectric, forming a gate electrode, forming a side wall 600, LDD (lightly doping drain) implantation, dopant activation, forming Si_{1-y}Ge_{y} and/or Si_{1-z}C_{z} raised source and drain structure by selective epitaxy, forming a metal silicide layer 700, forming an isolation dielectric 800 and forming a metal contact 900 need to be carried out in order to form a functional field effect transistor, as shown in FIG. 3 and FIG. 4.

Reference throughout this specification to “an embodiment,” “some embodiments,” “one embodiment”, “another example,” “an example,” “a specific example,” or “some examples,” means that a particular feature, structure, material, or characteristic described in connection with the embodiment or example is included in at least one embodiment or example of the present disclosure. Thus, the appearances of the phrases such as “in some embodiments,” “in one embodiment”, “in an embodiment”, “in another example,” “in an example,” “in a specific example,” or “in some examples,” in various places throughout this specification are not necessarily referring to the same embodiment or example of the present disclosure. Furthermore, the particular features, structures, materials, or characteristics may be combined in any suitable manner in one or more embodiments or examples.

Although explanatory embodiments have been shown and described, it would be appreciated by those skilled in the art that changes, alternatives, and modifications may be made in the embodiments without departing from spirit and principles of the disclosure. Such changes, alternatives, and modifications all fall into the scope of the claims and their equivalents.

What is claimed is:

1. A field effect transistor, comprising:
a substrate;
an ultra-thin insulator layer formed on the substrate, wherein a material of the ultra-thin insulator layer is a monocrystalline rare earth oxide or a monocrystalline beryllium oxide;
an ultra-thin semiconductor monocrystalline film formed on the ultra-thin insulator layer; and
a gate stack formed on the ultra-thin semiconductor monocrystalline film, and comprising a gate dielectric and a gate electrode formed on the gate dielectric.

2. The field effect transistor according to claim 1, wherein the monocrystalline rare earth oxide comprises at least one oxide selected from a group consisting of: (Gd₁₋ₓErₓ)₂O₃, (Gd₁₋ₓNdₓ)₂O₃, (Er₁₋ₓNdₓ)₂O₃, (Er₁₋ₓLaₓ)₂O₃, (Pr₁₋ₓLaₓ)₂O₃, (Pr₁₋ₓNdₓ)₂O₃, and (Pr₁₋ₓGdₓ)₂O₃, where x is within a range of 0 to 1.

3. The field effect transistor according to claim 1, wherein the ultra-thin insulator layer has a thickness of less than 20 nm.

4. The field effect transistor according to claim 1, the ultra-thin semiconductor monocrystalline film has a thickness of less than 20 nm.

5. The field effect transistor according to claim 1, further comprising:
a back gate formed in the substrate and immediately adjacent to the ultra-thin insulator layer.

6. The field effect transistor according to claim 1, wherein the ultra-thin insulator layer and the ultra-thin semiconductor monocrystalline film are formed by epitaxial growth.

7. The field effect transistor according to claim 1, wherein a material of the substrate comprises at least one semiconductor selected from a group consisting of: monocrystalline Si, monocrystalline SiGe, and monocrystalline Ge.

8. The field effect transistor according to claim 1, wherein a material of the ultra-thin semiconductor monocrystalline film comprises: Si, Ge, Si_{1-y}Ge_{y}, Si_{1-z}C_{z}, a group III-V compound semiconductor material and a group II-VI compound semiconductor material, where y and z are each within a range of 0 to 1.

9. The field effect transistor according to claim 1, wherein the ultra-thin insulator layer is strained.

10. The field effect transistor according to claim 1, wherein the ultra-thin semiconductor monocrystalline film is strained.

11. A method for forming a field effect transistor, comprising steps of:
providing a substrate;
forming an ultra-thin insulator layer on the substrate, wherein a material of the ultra-thin insulator layer is a monocrystalline rare earth oxide or a monocrystalline beryllium oxide;
forming an ultra-thin semiconductor monocrystalline film on the ultra-thin insulator layer; and
forming a gate stack on the ultra-thin semiconductor monocrystalline film, wherein the gate stack comprises a gate dielectric and a gate electrode formed on the gate dielectric.

12. The method according to claim 11, wherein the monocrystalline rare earth oxide comprises at least one oxide selected from a group consisting of: (Gd₁₋ₓErₓ)₂O₃, (Gd₁₋ₓNdₓ)₂O₃, (Er₁₋ₓNdₓ)₂O₃, (Er₁₋ₓLaₓ)₂O₃, (Pr₁₋ₓLaₓ)₂O₃, (Pr₁₋ₓNdₓ)₂O₃, and (Pr₁₋ₓGdₓ)₂O₃, where x is within a range of 0 to 1.

13. The method according to claim 11, wherein the ultra-thin insulator layer has a thickness of less than 20 nm.

14. The method according to claim 11, wherein the ultra-thin semiconductor monocrystalline film has a thickness of less than 20 nm.

15. The method according to claim 11, further comprising:
forming a back gate in the substrate and immediately adjacent to the ultra-thin insulator film before forming the gate stack.

16. The method according to claim 11, wherein the ultra-thin insulator layer and the ultra-thin semiconductor monocrystalline film are formed by epitaxial growth.

17. The method according to claim 11, wherein a material of the substrate comprises at least one semiconductor selected from a group consisting of: monocrystalline Si, monocrystalline SiGe, and monocrystalline Ge.

18. The method according to claim 11, wherein a material of the ultra-thin semiconductor monocrystalline film comprises: Si, Ge, Si_{1-y}Ge_{y}, Si_{1-z}C_{z}, a group III-V compound semiconductor material and a group II-VI compound semiconductor material, where y and z are each within a range of 0 to 1.

19. The method according to claim 11, wherein the ultra-thin insulator layer is strained.

20. The method according to claim 11, wherein the ultra-thin semiconductor monocrystalline film is strained.
